(19) United States
(12) Patent Application Publication
(10) Pub. No.: US 2020/0083452 A1
(43) Pub. Date: Mar. 12, 2020

(54) APPARATUS FOR VACUUM PROCESSING OF A SUBSTRATE, SYSTEM FOR VACUUM PROCESSING OF A SUBSTRATE, AND METHOD FOR TRANSPORTATION OF A SUBSTRATE CARRIER AND A MASK CARRIER IN A VACUUM CHAMBER

(71) Applicant: Applied Materials, Inc., Santa Clara, CA (US)

(72) Inventors: Matthias HEYMANNS, Münster (DE); Stefan BANGERT, Steinau (DE); Oliver HEIMEL, Wabern (DE); Andreas SAUER, Großostheim (DE); Sebastian Gunther ZANG, Mainaschaff (DE)

(73) Assignees: Applied Materials, Inc., Santa Clara, CA (US); Applied Materials, Inc., Santa Clara, CA (US)

(21) Appl. No.: 15/743,614

(22) PCT Filed: Feb. 24, 2017
(86) PCT No.: PCT/EP2017/054358

§ 371 Date: Jan. 10, 2018

(51) Int. Cl. H01L 51/00; C23C 14/04; C23C 14/56; H01L 51/56

(52) U.S. Cl. CPC H01L 51/0012; C23C 14/042; H01L 51/56; H01L 51/001; H01L 51/0011; C23C 14/56

(57) ABSTRACT

The present disclosure provides an apparatus (200) for vacuum processing of a substrate (10). The apparatus (200) includes a vacuum chamber, a first track arrangement (110) configured for transportation of a substrate carrier (120), a second track arrangement (130) configured for transportation of a mask carrier (140), and a holding arrangement configured for positioning the substrate carrier (120) and the mask carrier (140) with respect to each other. The first track arrangement (110) includes a first portion configured to support the substrate carrier (120) at a first end (12) of the substrate (10) and a second portion configured to support the substrate carrier (120) at a second end (14) of the substrate (10) opposite the first end (12) of the substrate (10). The second track arrangement (120) includes a further first portion configured to support the mask carrier (140) at a first end (22) of a mask (20) and a further second portion configured to support the mask carrier (140) at a second end (24) of the mask (20) opposite the first end (22) of the mask (20). A first distance (D) between the first portion and the second portion of the first track arrangement (110) and a second distance (D′) between the further first portion and the further second portion of the second track arrangement (130) are essentially the same.

### FIELD

Embodiments of the present disclosure relate to an apparatus for vacuum processing of a substrate, a system for vacuum processing of a substrate, and a method for transportation of a substrate carrier and a mask carrier in a vacuum chamber. Embodiments of the present disclosure particularly relate to carriers for holding substrates and masks used in the manufacture of organic light-emitting diode (OLED) devices.

### BACKGROUND

Techniques for layer deposition on a substrate include, for example, thermal evaporation, physical vapor deposition (PVD), and chemical vapor deposition (CVD). Coated substrates may be used in several applications and in several technical fields. For instance, coated substrates may be used in the field of organic light emitting diode (OLED) devices. OLEDs can be used in the manufacture of television screens, computer monitors, mobile phones, other hand-held devices, and the like for displaying information. An OLED device, such as an OLED display, may include one or more layers of an organic material situated between two electrodes that are all deposited on a substrate.

The functionality of an OLED device can depend on a coating thickness of the organic material. The thickness has to be within a predetermined range. In the production of OLED devices, there are technical challenges with respect to the deposition of evaporated materials in order to achieve high resolution OLED devices. In particular, accurate and smooth transportation of substrate carriers and mask carriers through a processing system remains challenging. Further, a precise alignment of the substrate with respect to the mask is crucial for achieving high quality processing results, e.g. for production of high resolution OLED devices.

In view of the above, new carriers for vacuum processing of a substrate, systems for vacuum processing of a substrate, and methods for transportation of a substrate carrier and a mask carrier in a vacuum chamber that overcome at least some of the problems in the art are beneficial. The present disclosure particularly aims at providing carriers that can be efficiently transported in a vacuum chamber.

### SUMMARY

In light of the above, an apparatus for vacuum processing of a substrate, a system for vacuum processing of a substrate, and a method for transportation of a substrate carrier and a mask carrier in a vacuum chamber are provided. Further aspects, benefits, and features of the present disclosure are apparent from the claims, the description, and the accompanying drawings.

According to an aspect of the present disclosure, an apparatus for vacuum processing of a substrate is provided. The apparatus includes a vacuum chamber, a first track arrangement configured for transportation of a substrate carrier, a second track arrangement configured for transportation of a mask carrier, and a holding arrangement configured for positioning the substrate carrier and the mask carrier with respect to each other. The first track arrangement includes a first portion configured to support the substrate carrier at a first end of the substrate and a second portion configured to support the substrate carrier at a second end of the substrate opposite the first end of the substrate. The second track arrangement includes a further first portion configured to support the mask carrier at a first end of the mask and a further second portion configured to support the mask carrier at a second end of the mask opposite the first end of the mask. A first distance between the first portion and the second portion of the first track arrangement and a second distance between the further first portion and the further second portion of the second track arrangement are essentially the same.

According to another aspect of the present disclosure, a system for vacuum processing of a substrate is provided. The system includes the apparatus for vacuum processing of a substrate according to the embodiments described herein, the substrate carrier and the mask carrier.

According to a further aspect of the present disclosure, a method for transportation of a substrate carrier and a mask carrier in a vacuum chamber is provided. The method includes contactlessly transporting the substrate carrier on a first track arrangement and the mask carrier on a second track arrangement, and contactlessly transporting the substrate carrier on the second track arrangement and the mask carrier on the first track arrangement.

According to an aspect of the present disclosure, an apparatus for vacuum processing of a substrate is provided. The apparatus includes a vacuum chamber, a first track arrangement extending in a first direction and configured for transportation of a substrate carrier at least in the first direction, a second track arrangement extending in the first direction and configured for transportation of a mask carrier at least in the first direction, and a holding arrangement configured for positioning the substrate carrier and the mask carrier with respect to each other. The first track arrangement is sized to be able to also transport the mask carrier and the second track arrangement is sized to be able to also transport the substrate carrier.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1A shows a schematic view of a first track arrangement and a substrate carrier according to embodiments described herein;

FIG. 1B shows a schematic view of a second track arrangement and a mask carrier according to embodiments described herein;

FIG. 2 shows a schematic view of an apparatus for vacuum processing of a substrate according to embodiments described herein;

FIG. 3A shows a schematic view of an apparatus for vacuum processing of a substrate having a holding arrangement according to embodiments described herein;

FIG. 3B shows a schematic view of an apparatus for vacuum processing of a substrate having a holding arrangement according to embodiments described herein;

FIGS. 4A and B show schematic views of an apparatus for vacuum processing of a substrate having a holding arrangement according to further embodiments described herein;

FIGS. 5A and B show schematic views of a transport arrangement for transportation of a carrier according to embodiments described herein;

FIG. 6 shows a schematic view of an apparatus for vacuum processing of a substrate according to further embodiments described herein;

FIG. 7 shows a schematic view of a system for vacuum processing of a substrate according to embodiments described herein; and

FIG. 8 shows a flow chart of a method for transportation of a substrate carrier and a mask carrier in a vacuum chamber according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

The present disclosure provides a first track arrangement for a substrate carrier and a second track arrangement for a mask carrier that are equally sized in at least one dimension. In other words, the mask carrier fits into the first track arrangement and the substrate carrier fits into the second track arrangement. The first track arrangement and the second track arrangement can be flexibly used while providing an accurate and smooth transportation of the carriers through the vacuum system. The holding arrangement allows for a precise alignment of the substrate with respect to the mask, or vice versa. A high quality processing results, e.g. for production of high resolution OLED devices, can be achieved.

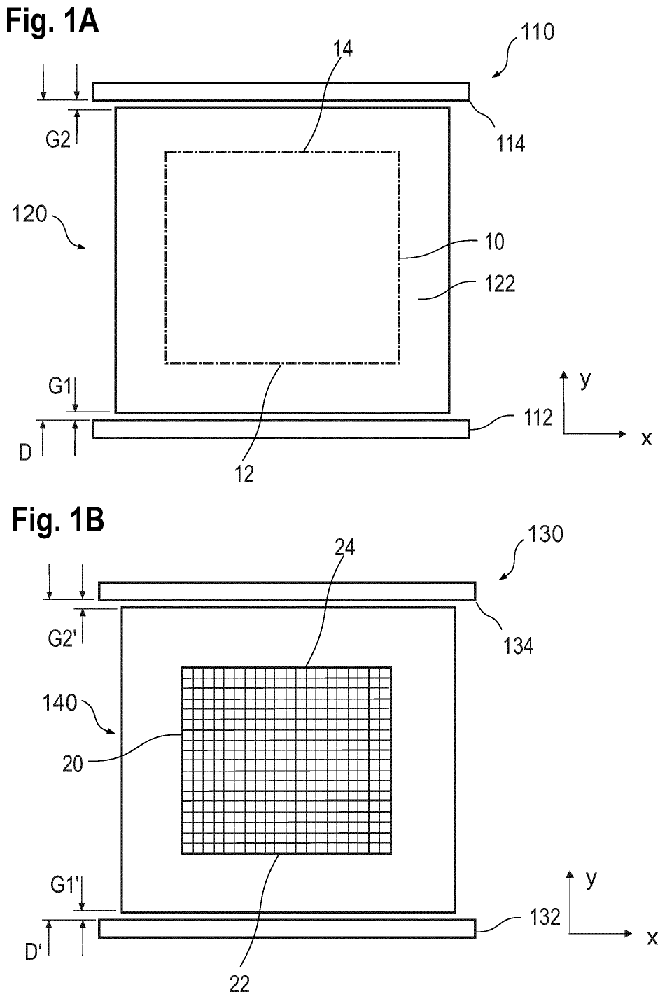

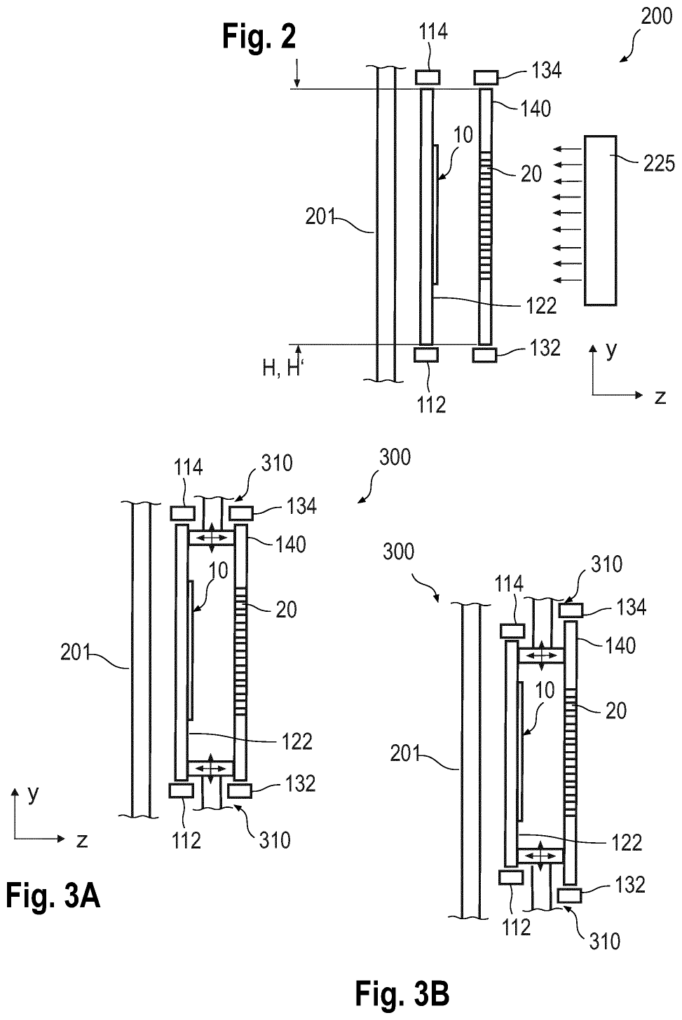

FIG. 1A shows a schematic view of a first track arrangement 110 and a substrate carrier 120. FIG. 1B shows a schematic view of a second track arrangement 130 and a mask carrier 140. FIG. 2 shows a schematic view of an apparatus 200 for vacuum processing of a substrate 10 according to embodiments described herein.

The apparatus 200 includes a vacuum chamber, the first track arrangement 110 configured for transportation of the substrate carrier 120, the second track arrangement 130 configured for transportation of the mask carrier 140, and a holding arrangement configured for positioning the substrate carrier 120 and the mask carrier 140 with respect to each other. The first track arrangement 110 includes a first portion, such as a first track 112, configured to support the substrate carrier 120 at a first end 12 of the substrate 10 and a second portion, such as a second track 114, configured to support the substrate carrier 120 at a second end 14 of the substrate 10 opposite the first end 12 of the substrate 10. The second track arrangement 130 includes a further first portion, such as a further first track 132, configured to support the mask carrier 140 at a first end 22 of the mask 20 and a further second portion, such as a further second track 134, configured to support the mask carrier 140 at a second end 24 of the mask 20 opposite the first end 22 of the mask 20. A first distance D between the first portion and the second portion of the first track arrangement 110 and a second distance D′ between the further first portion and the further second portion of the second track arrangement 130 are essentially equal or essentially the same. The distance(s) can be defined in a second direction (the y-direction), which can be an essentially vertical direction.

By providing essentially the same distances, namely the first distance D and the second distance D′, at the first track arrangement 110 and the second track arrangement 130, the first track arrangement 110 can be sized to be able to also transport the mask carrier 140, and the second track arrangement 130 can be sized to be able to also transport the substrate carrier 120. In other words, the mask carrier 140 fits into the first track arrangement 110 and the substrate carrier 120 fits into the second track arrangement 130. The first track arrangement 110 and the second track arrangement 130 can be flexibly used while providing an accurate and smooth transportation of the carriers through the vacuum system.

As used throughout the present disclosure, “essentially equal” or “essentially the same” is understood particularly when referring to distances, such as the distances D and D′ between the first and second portions, to allow for a slight deviation from an exact sameness/identity. As an example, the second distance D′ can be in a range of D±(5%×D), or can be in a range of D±(1%×D). The deviation can be due to manufacturing tolerances and/or thermal expansion. Yet, the distances are considered essentially equal or essentially the same.

The vacuum chamber can include a chamber wall 201. As exemplarily shown in FIG. 2, the first track arrangement 110 and the second track arrangement 130 can be arranged between the chamber wall 201 of the vacuum chamber and one or more deposition sources 225. In particular, the first track arrangement 110 can be arranged between the chamber wall 201 and the second track arrangement 130. Likewise, the second track arrangement 130 can be arranged between the first track arrangement 110 and the one or more deposition sources 225.

Referring to FIG. 1A, the substrate carrier 120 can include a support structure or body providing a support surface 122, which can be an essentially flat surface configured for contacting e.g. a back surface of the substrate 10. In particular, the substrate 10 can have a front surface (also referred to as “processing surface”) opposite the back surface and on which a layer is deposited during the vacuum processing, such as a vacuum deposition process. The first end 12 of the substrate 10 can be a first edge of the substrate 10, and the second end 14 of the substrate 10 can be a second edge of the substrate 10. The processing surface can extend between the first end or first edge and the second end or second edge. The first end (or first edge) and the second end (or second edge) can extend essentially parallel to each other, e.g., in the first direction. Likewise, the first end 22 of the mask 20 can be a first edge of the mask 20, and the second end 24 of the mask 20 can be a second edge of the mask. The first end (or first edge) and the second end (or second edge) can extend essentially parallel to each other, e.g., in the first direction, which can be the x-direction.

According to some embodiments, which can be combined with other embodiments described herein, the substrate carrier 120 can be an electrostatic chuck (E-chuck) providing an electrostatic force for holding the substrate 10 and optionally the mask at the substrate carrier 120, and particularly at the support surface 122. As an example, the substrate carrier 120 includes an electrode arrangement (not shown) configured to provide an attracting force acting on at least one of the substrate 10 and the mask 20.

According to some embodiments, the substrate carrier 120 includes the electrode arrangement having a plurality of electrodes configured to provide an attracting force for holding at least one of the substrate 10 and the mask 20 at the support surface 122, and a controller. The controller can be configured to apply one or more voltages to the electrode arrangement to provide the attracting force (also referred to as “chucking force”).

The plurality of electrodes of the electrode arrangement can be embedded in the body, or can be provided, e.g., placed, on the body. According to some embodiments, which can be combined with other embodiments described herein, the body is a dielectric body, such as a dielectric plate. The dielectric body can be fabricated from a dielectric material, preferably a high thermal conductivity dielectric material such as pyrolytic boron nitride, aluminum nitride, silicon nitride, alumina or an equivalent material, but may be made from such materials as polyimide. In some embodiments, the plurality of electrodes, such as a grid of fine metal strips, can be placed on the dielectric plate and covered with a thin dielectric layer.

According to some embodiments, which can be combined with other embodiments described herein, the substrate carrier 120 includes one or more voltage sources configured to apply one or more voltages to the plurality of electrodes. In some implementations, the one or more voltage sources are configured to ground at least some electrodes of the plurality of electrodes. As an example, the one or more voltage sources can be configured to apply a first voltage having a first polarity, a second voltage having a second polarity, and/or ground to the plurality of electrodes.

The electrode arrangement, and particularly the plurality of electrodes, can be configured to provide the attracting force, such as a chucking force. The attracting force can be a force acting on the substrate 10 and/or the mask 20 at a certain relative distance between the plurality of electrodes (or the support surface 122) and the substrate 10 and/or the mask 20. The attracting force can be an electrostatic force provided by the voltages applied to the plurality of electrodes. A magnitude of the attracting force may be determined by the voltage polarity and a voltage level. The attracting force can be changed by altering the voltage polarities and/or by altering the voltage level(s).

The substrate 10 can be attracted by the attracting force provided by the substrate carrier 120 towards the support surface 122 (e.g., in the third direction (z-direction) perpendicular to the first direction (x-direction) and/or a second direction (y-direction). The attracting force can be strong enough to hold the substrate 10 e.g. in an essentially vertical position by frictional forces. In particular, the attracting force can be configured to fix the substrate 10 on the support surface 122 essentially immoveable. For example, to hold a 0.5 mm glass substrate in a vertical position using friction forces, an attracting pressure of about 50 to 100 N/m2 (Pa) can be used, depending on the friction coefficient.

In the present disclosure, a “mask carrier” is to be understood as a carrier which is configured for holding a mask. For instance, the mask may be an edge exclusion mask or a shadow mask. An edge exclusion mask is a mask which is configured for masking one or more edge regions of the substrate, such that no material is deposited on the one or more edge regions during the coating of the substrate. A shadow mask is mask for configured for masking a plurality of features which are to be deposited on the substrate. For instance, the shadow mask can include a plurality of small openings, e.g. a grid of small openings.

According to some embodiments, which can be combined with other embodiments described herein, the first track arrangement 110 and the second track arrangement 130 extend in the first direction (x-direction), which can be an essentially horizontal direction. In particular, the first portion, the second portion, the further first portion and the further second portion can all extend in the first direction. In other words, the first portion, the second portion, the further first portion and the further second portion can extend essentially parallel to each other. The extension of the first portion, the second portion, the further first portion and the further second portion can also be referred to as “longitudinal extension”.

In some implementations, the first track arrangement 110 is configured for transportation of the substrate carrier 120 at least in the first direction. Likewise, the second track arrangement 130 can be configured for transportation of the mask carrier 140 at least in the first direction. The first direction can also be referred to as “transport direction”.

According to some embodiments, the first portion, such as the first track 112, and the further first portion, such as the further first track 132, are arranged in a first plane defined by the first direction and another direction perpendicular to the first direction. Likewise, the second portion, such as the second track 114, and the further second portion, such as to further second track 134, can be arranged in a second plane defined by the first direction and the other direction. The first plane and the second plane can be essentially parallel to each other. In some implementations, the first plane and the second plane can be essentially vertical planes or essentially horizontal planes.

According to some embodiments, which can be combined with other embodiments described herein, the first direction can be a horizontal direction (x direction). The other direction can be another horizontal direction or a vertical direction. As an example, the other direction can be the second direction (y direction), which can be an essentially vertical direction, or can be the third direction (z direction), which can be an essentially horizontal direction.

In some embodiments, the first distance D and the second distance D′ are defined in a direction perpendicular to the first direction and the other direction, such as the second direction (y direction). The first distance D can be a spacing between the first portion and the second portion, e.g., a spacing between outermost surfaces or edge surfaces of the first portion and the second portion facing each other. Likewise, the second distance D′ can be a spacing between the further first portion and the further second portion, e.g., a spacing between outermost surfaces or edge surfaces of the further first portion and the further second portion facing each other.

According to some embodiments, a third distance or third spacing between the first portion, such as the first track 112, and the other first portion, such as the other first track 132, can be 100 mm or less, specifically 70 mm or less, specifically 50 mm or less, and more specifically 40 mm or less. Likewise, a fourth distance or fourth spacing between the second portion, such as the second track 114 and the other second portion, such as the other second track 134, can be 200 mm or less, 100 mm or less, specifically 70 mm or less, and more specifically 50 mm or less. The third distance and the fourth distance can be essentially the same. In some implementations, the third distance and the fourth distance can be defined in the second direction (y direction), which can be a vertical direction, or can be defined in the third direction (z direction), which can be a horizontal direction. The latter case is illustrated in FIG. 2. The distances or spacings can be defined between edges or surfaces of the respective portions facing each other.

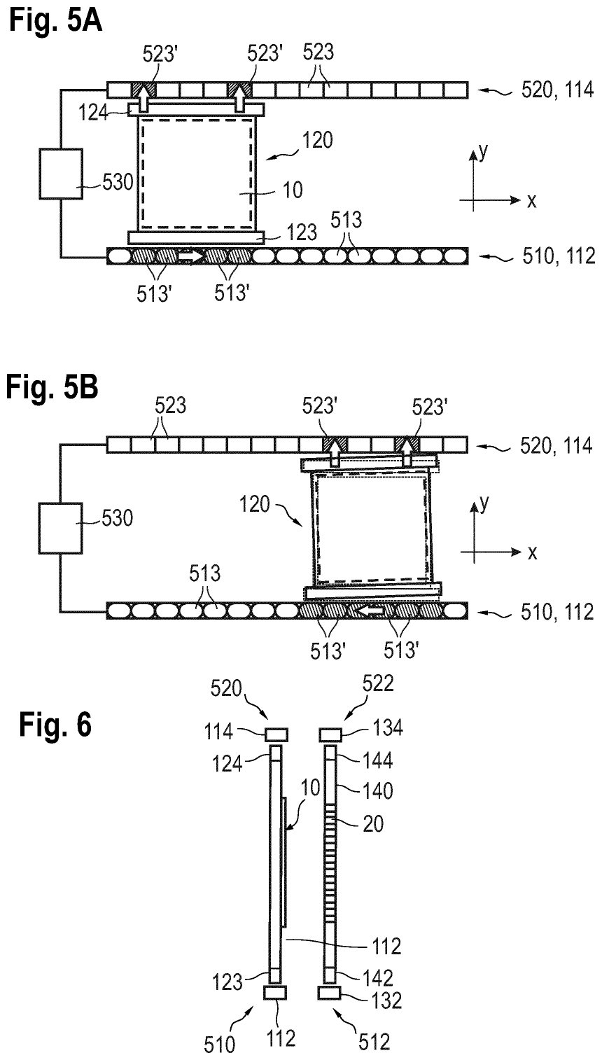

According to some embodiments, which can be combined with other embodiments described herein, the apparatus 200 can be configured for contactless levitation and/or contactless transportation of the substrate carrier 120 and/or the mask carrier 140. As an example, the apparatus 200 can include a guiding structure configured for contactless levitation of the substrate carrier 120 and/or the mask carrier 140. Likewise, the apparatus 200 can include a drive structure configured for contactless transportation of the substrate carrier 120 and/or the mask carrier 140. The contactless levitation and the contactless transportation are further explained with respect to FIGS. 5A, 5B, and 6.

In the present disclosure, a track or track arrangement configured for contactless transportation is to be understood as a track or track arrangement which is configured for contactless transportation of a carrier, particularly a substrate carrier or a mask carrier. The term “contactless” can be understood in the sense that the weight of the currier, e.g. of the substrate carrier or mask carrier, is not held by a mechanical contact or mechanical forces, but is held by a magnetic force. In particular, the carrier can be held in a levitating or floating state using magnetic forces instead of mechanical forces. For example, in some implementations, there can be no mechanical contact between the carrier and the transportation track, particularly during levitation, movement and positioning of the substrate carrier and/or mask carrier.

The contactless levitation and/or transportation of the carrier(s) is beneficial in that no particles are generated during transportation, for example due to mechanical contact with guide rails. An improved purity and uniformity of the layers deposited on the substrate 10 can be provided, since particle generation is minimized when using the contactless levitation and/or transportation.

In some implementations, the substrate carrier 120 has a first dimension H (or first extension) and the mask carrier 140 has a further first dimension H′ (or further first extension). The first dimension H and the further first dimension H′ can be defined in a direction perpendicular to the first direction. As an example, the first dimension H and the further first dimension H′ can be defined in the second direction, which can be a vertical direction. The first dimension H and the further first dimension H′ can be a height of the substrate carrier 120 and the mask carrier 140, respectively. The first dimension H and the further first dimension H′ can be essentially the same. In other words, the substrate carrier 120 can fit between the first portion and the second portion of the first track arrangement 110 as well as between the further first portion and the further second portion of the second track arrangement 130. Likewise, the mask carrier 140 can fit between the first portion and the second portion of the first track arrangement 110 as well as between the further first portion and the further second portion of the second track arrangement 130.

According to some embodiments, the first dimension H and the further first dimension H′ are equal to or less than the first distance D and the second distance D′. In other words, the substrate carrier 120 and the mask carrier 140 are smaller than the gap between the first portions and the second portions. A first gap G1 can be provided between the first portion of the first track arrangement 110 and a first edge (e.g., a lower edge) of the substrate carrier 120. A second gap G2 can be provided between the second portion of the first track arrangement 110 and a second edge (e.g., an upper edge) of the substrate carrier 120. The first edge and the second edge can be opposite edges of the substrate carrier 120. Likewise, a further first gap G1′ can be provided between the further first portion of the second track arrangement 130 and a first edge (e.g., a lower edge) of the mask carrier 140. A further second gap G2′ can be provided between the further second portion of the second track arrangement 130 and a second edge (e.g., an upper edge) of the mask carrier 140. The first edge and the second edge can be opposite edges of the mask carrier 140.

The first gap G1, the second gap G2, the further first gap G1′ and the further second gap G2′ can be essentially the same or equal. A dimension or width of the gap(s) can be defined in a direction perpendicular to the first direction, such as the second direction. As an example, the first gap G1, the second gap G2, the further first gap G1′ and the further second gap G2′ can be less than 30 mm, specifically less than 10 mm, and more specifically less than 5 mm. As an example, at least one of the first gap G1, the second gap G2, the further first gap G1′ and the further second gap G2′ can be in the range between 1 and 5 mm, and preferably in the range between 1 and 3 mm.

One or more deposition sources 225 can be provided in the vacuum chamber. The substrate carrier 120 can be configured to hold the substrate 10 during a vacuum deposition process. The vacuum system can be configured for evaporation of e.g. an organic material for the manufacture of OLED devices. As an example, the one or more deposition sources 225 can be evaporation sources, particularly evaporation sources for depositing one or more organic materials on a substrate to form a layer of an OLED device. The substrate carrier 120 for supporting the substrate 10 can be transported into and through the vacuum chamber, and in particular into and/or through a deposition area, along a transportation path, such as a linear transportation path, provided by the first track arrangement 110.

The material can be emitted from the one or more deposition sources 225 in an emission direction towards the deposition area in which the substrate 10 to be coated is located. For instance, the one or more deposition sources 225 may provide a line source with a plurality of openings and/or nozzles which are arranged in at least one line along the length of the one or more deposition sources 225. The material can be ejected through the plurality of openings and/or nozzles.

The apparatus of the present disclosure can be configured for positioning of a carrier, particularly a substrate carrier and/or a mask carrier. In particular, the apparatus can be configured for moving a substrate carrier and/or a mask carrier along a track arrangement. More specifically, the apparatus can be configured for positioning the substrate carrier in a first position by moving the substrate carrier along the first track arrangement. Additionally, the apparatus can be configured for positioning the mask carrier in a second position by moving the mask carrier along the second track arrangement. For instance, the first track arrangement and the second track arrangement can be configured for contactless transportation. Accordingly, the apparatus can be configured for moving the substrate carrier and the mask carrier independently from each other, such that the substrate carrier and the mask carrier can be positioned relatively to each other, e.g. for aligning the substrate carrier with the mask carrier.

According to some embodiments, which can be combined with other embodiments described herein, the carriers are configured for holding or supporting the substrate and the mask in a substantially vertical orientation. As used throughout the present disclosure, “substantially vertical” is understood particularly when referring to the substrate orientation, to allow for a deviation from the vertical direction or orientation of ±20° or below, e.g. of ±10° or below. This deviation can be provided for example because a substrate support with some deviation from the vertical orientation might result in a more stable substrate position. Further, fewer particles reach the substrate surface when the substrate is tilted forward. Yet, the substrate orientation, e.g., during the vacuum deposition process, is considered substantially vertical, which is considered different from the horizontal substrate orientation, which may be considered as horizontal±20° or below.

The term “vertical direction” or “vertical orientation” is understood to distinguish over “horizontal direction” or “horizontal orientation”. That is, the “vertical direction” or “vertical orientation” relates to a substantially vertical orientation e.g. of the carriers, wherein a deviation of a few degrees, e.g. up to 10° or even up to 15°, from an exact vertical direction or vertical orientation is still considered as a “substantially vertical direction” or a “substantially vertical orientation”. The vertical direction can be substantially parallel to the force of gravity.

The embodiments described herein can be utilized for evaporation on large area substrates, e.g., for OLED display manufacturing. Specifically, the substrates for which the structures and methods according to embodiments described herein are provided, are large area substrates. For instance, a large area substrate or carrier can be GEN 4.5, which corresponds to a surface area of about 0.67 m² (0.73×0.92 m), GEN 5, which corresponds to a surface area of about 1.4 m² (1.1 m×1.3 m), GEN 7.5, which corresponds to a surface area of about 4.29 m² (1.95 m×2.2 m), GEN 8.5, which corresponds to a surface area of about 5.7 m² (2.2 m×2.5 m), or even GEN 10, which corresponds to a surface area of about 8.7 m² (2.85 m×3.05 m). Even larger generations such as GEN 11 and GEN 12 and corresponding surface areas can similarly be implemented. Half sizes of the GEN generations may also be provided in OLED display manufacturing.

According to some embodiments, which can be combined with other embodiments described herein, the substrate thickness can be from 0.1 to 1.8 mm. The substrate thickness can be about 0.9 mm or below, such as 0.5 mm. The term “substrate” as used herein may particularly embrace substantially inflexible substrates, e.g., a wafer, slices of transparent crystal such as sapphire or the like, or a glass plate. However, the present disclosure is not limited thereto and the term “substrate” may also embrace flexible substrates such as a web or a foil. The term “substantially inflexible” is understood to distinguish over “flexible”. Specifically, a substantially inflexible substrate can have a certain degree of flexibility, e.g. a glass plate having a thickness of 0.9 mm or below, such as 0.5 mm or below, wherein the flexibility of the substantially inflexible substrate is small in comparison to the flexible substrates.

According to embodiments described herein, the substrate may be made of any material suitable for material deposition. For instance, the substrate may be made of a material selected from the group consisting of glass (for instance soda-lime glass, borosilicate glass, and the like), metal, polymer, ceramic, compound materials, carbon fiber materials or any other material or combination of materials which can be coated by a deposition process.

The term “masking” may include reducing and/or hindering a deposition of material on one or more regions of the substrate 10. The masking may be useful, for instance, in order to define the area to be coated. In some applications, only parts of the substrate 10 are coated and the parts not to be coated are covered by the mask.

FIG. 3A shows a schematic view of an apparatus 300 for vacuum processing according to further embodiments described herein.

The apparatus 300 includes the holding arrangement 310. The holding arrangement 310 can be configured to position the substrate carrier 120 and the mask carrier 140 with respect to each other. As an example, the holding arrangement 310 can be configured to align the substrate carrier 120 and the mask carrier 140 with respect to each other by moving the substrate carrier 120 while keeping the mask carrier 140 stationary, or by moving the mask carrier 140 while keeping the substrate carrier 120 stationary. In yet further examples, both the substrate carrier 120 and the mask carrier 140 can be moved to position or align the substrate carrier 120 and the mask carrier 140 with respect to each other.

According to some embodiments, which can be combined with other embodiments described herein, the holding arrangement 310 can be configured for holding the substrate carrier 120 and/or the mask carrier 140. The holding arrangement 310 can be at least partially arranged between the first track arrangement and the second track arrangement. As an example, one or more holding devices of the holding arrangement 310 can be arranged between the first portion, such as the first track 112, and the further first portion, such as the further first track 132. One or more further holding devices of the holding arrangement 310 can be arranged between the second portion, such as the second track 114, and the further second portion, such as the further second track 134.

In some implementations, the holding arrangement 310 can be arranged at a top wall and/or a bottom wall of the vacuum chamber. An example, the holding arrangement 310 can extend from the bottom wall to a position between the first portion, such as the first track 112, and the further first portion, such as the further first track 132. Likewise, the holding arrangement 310 can extend from the top wall to a position between the second portion, such as the second track 114, and the further second portion, such as the further second track 134.

According to some embodiments, the holding arrangement 310 is configured for holding the mask carrier 140 and/or the substrate carrier 120 in a predetermined position. Further, optionally, the holding arrangement 310 can be configured for positioning the mask carrier 140 relative to the substrate carrier 120 or for positioning the substrate carrier 120 relative to the mask carrier 140. By providing the holding arrangement 310 between the first track arrangement and the second track arrangement, an improved alignment of the substrate carrier 120 and the mask carrier 140 can be provided.

In some implementations, the holding arrangement 310 includes the one or more holding devices configured to be movable in a moving direction being different than a substrate transport direction (i.e., the first direction). For instance, the one or more holding devices can be configured to be movable in a direction substantially parallel and/or in a direction substantially perpendicular to a plane of the substrate surface. In FIG. 3A, moving directions of the one or more holding devices are indicated by the double sided arrows depicted on the one or more holding devices.

In some implementations, the mask carrier 140 can be transported on the second track arrangement to a predetermined position at which the holding arrangement 310 is provided, the movable holding devices can move towards the mask carrier 140 in order to hold the mask carrier 140 in the predetermined position. Thereafter, the substrate carrier 120 can be transported on the first track arrangement to a predetermined position corresponding to the mask carrier 140. The one or more holding devices holding the mask carrier 140 can be configured to hold the substrate carrier 120, e.g., by chucking the substrate carrier 120 using a chucking force, such as a magnetic or electromagnetic force.

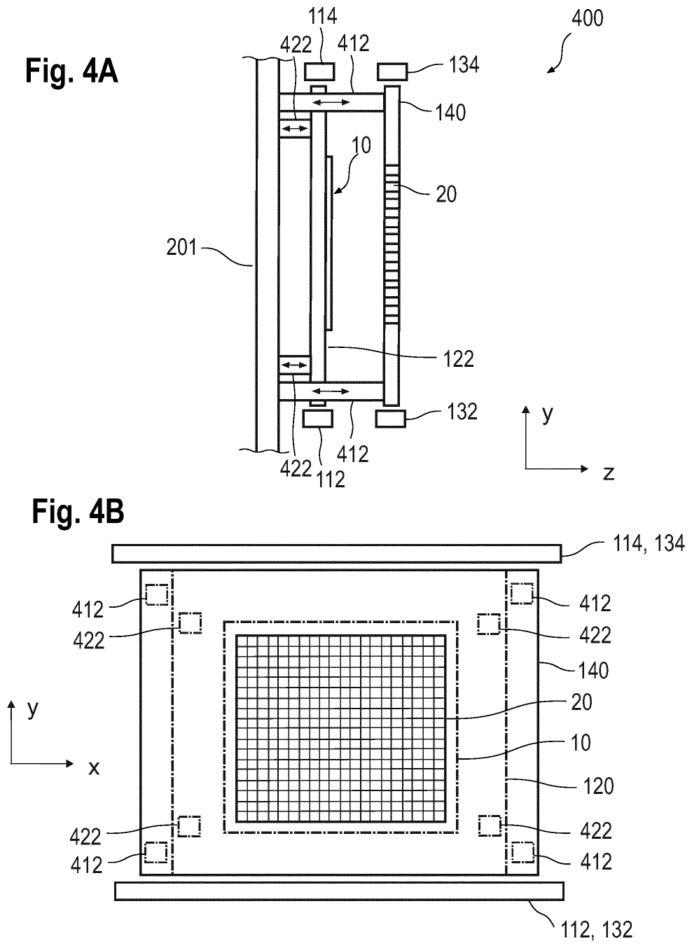

According to some embodiments, the same holding devices can be used for holding the substrate carrier 120 and the mask carrier 140, as it is illustrated in the example of FIG. 3A. In further embodiments, different holding devices can be used for holding the substrate carrier 120 and the mask carrier 140, respectively, as it is illustrated in the example of FIGS. 4A and B.

According to some embodiments, which can be combined with other embodiments described herein, the holding arrangement 310 can include an alignment system configured for aligning the substrate carrier 120 relative to the mask carrier 140. In particular, the alignment system can be configured to adjust the position of the substrate carrier 120 with respect to the mask carrier 140. For example, the alignment system can include two or more alignment actuators, for example four alignment actuators. For instance, the alignment system can be configured for aligning the substrate carrier 120 holding the substrate 10 relative to the mask carrier 140 holding the mask 20 in order to provide for a proper alignment between the substrate 10 and the mask 20 during material deposition, e.g. of the organic material.

In some implementations, the mask carrier 140 may be moved into a predetermined mask position on the second track arrangement. Thereafter, the holding arrangement 310 may move forward to hold the mask carrier 140. After the mask carrier 140 is positioned, the substrate carrier 120 may be moved into a predetermined substrate position. Then the substrate carrier 120 can be aligned, e.g. by an alignment system as described herein, with respect to the mask carrier 140.

In some implementations, the holding arrangement includes one or more alignment actuators for positioning the substrate carrier 120 and the mask carrier 140 with respect to each other. As an example, the two or more alignment actuators can be piezoelectric actuators for positioning the substrate carrier 120 and the mask carrier 140 with respect to each other. However, the present disclosure is not limited to piezoelectric actuators. As an example, the two or more alignment actuators can be electric or pneumatic actuators. The two or more alignment actuators can for example be linear alignment actuators. In some implementations, the two or more alignment actuators can include at least one actuator selected from the group consisting of: a stepper actuator, a brushless actuator, a DC (direct current) actuator, a voice coil actuator, a piezoelectric actuator, and any combination thereof.

According to some embodiments, the one or more alignment actuators can be provided between the first transport arrangement and the second transport arrangement. In particular, the one or more alignment actuators can be provided between the substrate carrier 120 and the mask carrier 140. The one or more alignment actuators can be implemented in a space-saving manner, reducing a footprint of the apparatus.

According to some embodiments of the present disclosure, the holding arrangement 310 may be configured for holding the mask carrier and/or the substrate carrier. According to some embodiments which can be combined with other embodiments described herein, the holding arrangement can include at least one holding device and may include at least two holding devices, e.g. three holding devices, four holding devices, or more. A holding device can have a reception which can be configured for being connected to at least one mating connecting element provided on the mask carrier or the substrate carrier. For instance, the at least one mating connecting element may be configured as a locking bolt. When the mask carrier and/or the substrate carrier is in a predetermined position, the holding arrangement and the locking bolts can beneficially be employed for holding the correct position. According to some embodiments, the holding arrangement may also include holding devices, wherein the holding devices are connected to a mask carrier and/or a substrate carrier with magnetic forces. For example, the one or more holding devices may include an electromagnet, which can be switched on for engaging the holding device to a mask carrier or a substrate carrier. According to some embodiments, which can be combined with other embodiments described herein, a holding arrangement can include two holding devices, i.e. one holding device for holding a mask carrier and one holding device for holding a substrate carrier. For example two magnetic holding devices can be provided for a holding arrangement.

FIG. 3B shows a schematic view of an apparatus 300 for vacuum processing according to further embodiments described herein.

The apparatus 300 includes the holding arrangement 310. The holding arrangement 310 can be configured to position the substrate carrier 120 and the mask carrier 140 with respect to each other as described above, e.g. with respect to FIG. 3A.

According to some embodiments, which can be combined with other embodiments described herein, the holding arrangement 310 can be configured for holding the substrate carrier 120 and/or the mask carrier 140. The holding arrangement 310 can be at least partially arranged between the first track arrangement and the second track arrangement. As an example, one or more holding devices of the holding arrangement 310 can be arranged between the first portion, such as the first track 112, and the further first portion, such as the further first track 132. One or more further holding devices of a holding arrangement 310 can be arranged between the second portion, such as the second track 114, and the further second portion, such as the further second track 134. According to some embodiments, a holding device arranged between the first track arrangement and the second track arrangement can have a first element to hold the mask carrier and a second element to hold the substrate carrier. The first element and the second element can, for example, be magnetic elements or a locking bolt.

In some implementations, the holding arrangement 310 can be arranged at a top wall and/or a bottom wall of the vacuum chamber. The holding arrangement is provided at least partially within the gap between the mask carrier and the substrate carrier or respective track portions. As an example, the holding arrangement 310 can extend from the bottom wall to a position between the first portion, such as the first track 112, and the further first portion, such as the further first track 132. Likewise, the holding arrangement 310 can extend from the top wall to a position between the second portion, such as the second track 114, and the further second portion, such as the further second track 134. According to some embodiments of the present disclosure, which can be combined with other embodiments described herein, a holding arrangement provided in the gap between the first track and the second track, e.g. a mask track and a carrier track can be provided for an apparatus 300, wherein a mask carrier is larger than a substrate carrier or vice versa. Having the mask carrier larger than the substrate carrier reduces the risk of chamber components, e.g. a portion of a chamber wall be coated with material. For example, there may be an offset between first track 112 and the further first track. Additionally or alternatively, there may be an offset between the second track 114 and the further second track 134.

By providing the holding arrangement 310 between the first track arrangement and the second track arrangement, an improved alignment of the substrate carrier 120 and the mask carrier 140 can be provided. For example, the length (dimension) of the holding arrangement may be reduced such inaccuracies may not be increased by a leverage of the length of the holding arrangement. According to one embodiment, a holding arrangement can be provided at least partially in a gap between the first track and the second track. The holding arrangement is configured to hold a first carrier, e.g. a substrate carrier, at a side facing the gap and is configured to hold a second carrier, e.g. a mask carrier, at a side facing the gap. Further, details and aspects of other embodiments described herein, may be provided to yield yet further embodiments.

FIGS. 4A and B show schematic views of an apparatus 400 for vacuum processing of a substrate 10 having a holding arrangement according to further embodiments described herein.

According to some embodiments, which can be combined with other embodiments described herein, the holding arrangement is configured for holding the substrate carrier 120 and/or the mask carrier 140. The holding arrangement can be arranged at a chamber wall 201, such as a side wall, of the vacuum chamber adjacent to the first track arrangement or the second track arrangement.

In some implementations, the holding arrangement includes one or more holding devices, such as one or more first holding devices 412 configured for holding the mask carrier 140 and/or one or more second holding devices 422 configured for holding the substrate carrier 120. The one or more holding devices can be configured to be movable in a moving direction being different than a substrate transport direction (i.e., the first direction). For instance, the one or more holding devices can be configured to be movable in a direction substantially perpendicular to a plane of the substrate surface, e.g., in the third direction. In FIG. 4A, a moving direction of the one or more holding devices is indicated by the double sided arrow depicted on the one or more holding devices.

In some implementations, the mask carrier 140 can be transported on the second track arrangement to a predetermined position at which the holding arrangement is provided. The one or more first holding devices 412 can move towards the mask carrier 140 in order to hold the mask carrier 140 in the predetermined position e.g. by chucking the mask carrier 140 using a chucking force, such as a magnetic or electromagnetic force. Thereafter, the substrate carrier 120 can be transported on the first track arrangement to a predetermined position corresponding to the mask carrier 140. At least one holding device of the one or more second holding devices 422 can move towards the substrate carrier 120 in order to hold the substrate carrier 120 in the predetermined position e.g. by chucking the substrate carrier 120 using a chucking force, such as a magnetic or electromagnetic force.

According to some embodiments, which can be combined with other embodiments described herein, an extension (e.g., a length) of the substrate carrier 120 in the first direction (x direction) and an extension (e.g., a length) of the mask carrier 140 in the first direction (x direction) are different. In particular, the substrate carrier 120 and the mask carrier 140 can have the same heights but different lengths. In particular, the length of the substrate carrier 120 can be less than the length of the mask carrier 140.

The length difference can be selected such that the one or more first holding devices 412, which can be mounted on the side wall of the vacuum chamber, can pass by the edges of the substrate carrier 120 to grab and hold the mask carrier 140. In particular, the one or more first holding devices 412 can pass the substrate carrier 120 without interfering with the substrate carrier 120.

In some implementations, the mask carrier 140 may be moved into a predetermined mask position on the second track arrangement and the substrate carrier 120 may be moved into a predetermined substrate position on the first track arrangement. Thereafter, the holding arrangement may move forward to hold the mask carrier 140 and the substrate carrier 120. Then, the substrate carrier 120 can be aligned, e.g. by an alignment system as described herein, with respect to the mask carrier 140, or vice versa.

According to some embodiments, which can be combined with other embodiments described herein, the holding arrangement can include an alignment system configured for aligning the substrate carrier 120 relative to the mask carrier 140 as it is described with respect to FIG. 3A. In particular, the alignment system can be configured to adjust the position of the substrate carrier 120 with respect to the mask carrier 140.

FIGS. 5A and B show schematic views of a transport arrangement for transportation of a carrier according to embodiments described herein. FIGS. 5A and B exemplarily illustrate the substrate carrier 120. FIG. 6 shows a schematic view of an apparatus for vacuum processing of a substrate 10 according to further embodiments described herein.

According to some embodiments, which can be combined with other embodiments described herein, the apparatus includes a drive structure configured for contactlessly moving the substrate carrier 120 and the mask carrier in the first direction. The drive structure can include the first portion, such as the first track 112, and the further first portion, such as the further first track 132. The apparatus can further include a guiding structure configured for contactlessly levitating the substrate carrier 120 and the mask carrier 140 in the vacuum chamber. The guiding structure can include the second portion, such as the second track 114, and the further second portion, such as the further second track 134. The drive structure can be a magnetic drive structure and/or the guiding structure can be a magnetic guiding structure.

In some implementations, the drive structure includes a first drive sub-structure 510 configured for contactlessly moving the substrate carrier 120 in the first direction and a second drive sub-structure 512 configured for contactlessly moving the mask carrier 140 in the first direction. The first drive sub-structure 510 can include the first portion, such as the first track 112, and the second drive sub-structure can include the further first portion, such as the further first track 132. Likewise, the guiding structure can include a first guiding sub-structure 520 configured for contactlessly levitating the substrate carrier 120 and a second guiding sub-structure 522 configured for contactlessly levitating the mask carrier 140. The first guiding sub-structure 520 can include the second portion, such as the second track 114, and the second guiding sub-structure 522 can include the further second portion, such as the further second track 134.

It is to be understood that the features as described in FIGS. 5A and B in connection with the first guiding sub-structure of the first track arrangement as well as in connection with the first drive sub-structure of the first track arrangement can also be applied to the second guiding sub-structure and the second drive sub-structure, respectively. Accordingly, with exemplarily reference to FIG. 6, the second guiding sub-structure 522 may be configured as a sub-guiding structure and the second drive sub-structure 512 may be configured as a drive sub-structure exemplarily described with reference to FIGS. 5A and 5B.

According to some embodiments, which can be combined with other embodiments described herein, the first guiding sub-structure 520 of the first track arrangement can be a first magnetic guiding sub-structure and the first drive sub-structure of the first track arrangement can be a first magnetic drive sub-structure. The first guiding sub-structure 520 may extend in a substrate carrier transportation direction, e.g. the x-direction. The first guiding sub-structure 520 can include a plurality of active magnetic elements 523. Further, the substrate carrier 120 may include a second passive magnetic element 124. For example, the second passive magnetic element 124 can be a bar or a rod of a ferromagnetic material which can be a portion of the substrate carrier 120. Alternatively, the second passive magnetic element 124 may be integrally formed with substrate carrier 120.

In some elements, at least one active magnetic element of the plurality of active magnetic elements 523 is configured for providing a magnetic force interacting with the second passive magnetic element 124 of the substrate carrier 120. In particular, the second passive magnetic element 124 and the plurality of active magnetic elements 523 of the first guiding sub-structure 520 can be configured for providing a magnetic levitation force for levitating the substrate carrier 120, as exemplarily indicated by the vertical arrows pointing towards the first guiding sub-structure 520. In other words, the plurality of active magnetic elements 523 are configured for providing a magnetic force on the second passive magnetic element 124 and, thus, on the substrate carrier 120. Accordingly, the plurality of active magnetic elements 523 can levitate the substrate carrier 120 contactlessly.

According to some embodiments, the first drive sub-structure 510 can include a plurality of further active magnetic elements 513. The further active magnetic elements 513 can be configured to drive the substrate carrier 120 along a transport direction, for example, along the x-direction. The plurality of further active magnetic elements 513 can form the first drive sub-structure 510 for moving the substrate carrier 120 while being levitated by the plurality of active magnetic elements 523. As exemplary shown in FIGS. 5A and 5B, the substrate carrier 120 can include a first passive magnetic element 123, e.g. a bar of ferromagnetic material configured to interact with the further active magnetic elements 513 of the first drive sub-structure 510. The first passive magnetic element 123 can be connected to the substrate carrier 120 or be integrally formed with the substrate carrier 120.

The further active magnetic elements 513 can be configured to interact with the first passive magnetic element 123 for providing a force along the transport direction. For example, the first passive magnetic element 123 can include a plurality of permanent magnets, which are arranged with an alternating polarity. The resulting magnetic fields of the first passive magnetic element 123 can interact with the plurality of further active magnetic elements 513 to move the substrate carrier 120 while being levitated.

In order to levitate the substrate carrier 120 with the plurality of active magnetic elements 523 and/or to move the substrate carrier 120 with the plurality of further active magnetic elements 513, the active magnetic elements can be controlled to provide adjustable magnetic fields. The adjustable magnetic field may be a static or a dynamic magnetic field. According to embodiments, which can be combined with other embodiments described herein, an active magnetic element as described herein can be configured for generating a magnetic field for providing a magnetic levitation force, for instance extending along a vertical direction, e.g. the y-direction shown in FIGS. 5A and 5B. Additionally or alternatively, an active magnetic element as described herein may be configured for providing a magnetic force extending along a transversal direction. In particular, an active magnetic element as described herein may be, or include, an element selected from the group consisting of: an electromagnetic device; a solenoid; a coil; a superconducting magnet; or any combination thereof.

As shown in FIGS. 5A and 5B, the first guiding sub-structure 520 may extend along the transport direction of the substrate carrier 120, i.e. the first direction or x-direction indicated in FIGS. 5A and 5B. In particular, the first guiding sub-structure 520 may have a linear shape extending along the first direction. The length of the first track arrangement, e.g. the first guiding sub-structure 520 and the first drive sub-structure 510, along the first direction may be from 1 to 30 m. For illustration purposes, the horizontal arrows in FIGS. 5A and 5B indicate a possible driving force of the first drive sub-structure 510 for moving the substrate carrier 120, e.g. from left to right and vice versa, along the first track arrangement.

As exemplarily shown in FIGS. 5A and 5B, two or more active magnetic elements 523′ can be activated by a substrate carrier controller 530 to generate a magnetic field for levitating the substrate carrier 120. For instance, during operation, the substrate carrier 120 may hang below the first guiding sub-structure 520 without mechanical contact. It to be understood that the second passive magnetic element 124 may have magnetic properties substantially along the length of the second passive magnetic element 124 in the transport direction. The magnetic field generated by the active magnetic elements 523′ interacts with the magnetic properties of the second passive magnetic element 124 to provide for a first magnetic levitation force and a second magnetic levitation force, as exemplarily indicated by the vertical arrows in FIGS. 5A and 5B. A contactless levitation, transportation and alignment of the substrate carrier 120 can be provided. In FIG. 5A, two active magnetic elements 523′ provide a magnetic force, which is indicated by the vertical arrows. The magnetic forces counteract the gravity force in order to levitate the substrate carrier 120. The substrate carrier controller 530 may be configured to individually control the two active magnetic elements 523′ to maintain the substrate carrier 120 in a levitating state.

In some embodiments, one or more further active magnetic elements 513′ can be controlled by the substrate carrier controller 530. The further active magnetic elements 513′ interact with the first passive magnetic element 123. For example, the first passive magnetic element 123 may include a set of alternating permanent magnets, to generate a driving force as exemplarily indicated by the horizontal arrow in FIG. 5A. For instance, the number of further active magnetic elements 513′, which are simultaneously controlled to provide the driving force, can be 1 to 3 or more. Accordingly, at a first position, the substrate carrier 120 is positioned below a first group of active magnetic elements and at a further, different position, the substrate is positioned below a further, different group of active magnetic elements. Typically, the substrate carrier controller 530 is configured to control which active magnetic elements provide a levitation force for a respective position. For example, the levitating force can be provided by subsequent active magnetic elements while the substrate carrier 120 is moving. Accordingly, the substrate carrier 120 may be handed over from one set of active magnetic elements to another set of active magnetic elements.

In the second position, as exemplarily shown in FIG. 5B, two active magnetic elements 523′ provide a first magnetic force indicated by the left vertical arrow and a second magnetic force indicated by right vertical arrow. The substrate carrier controller 530 may be configured to control the two active magnetic elements 523′ to provide for an alignment in a vertical direction, for example the y-direction indicated in FIG. 5B. Additionally or alternatively, the substrate carrier controller 530 may be configured to control the two active magnetic elements 523′ to provide for an alignment, wherein the carrier can be rotated in the x-y-plane. Both alignment movements can exemplarily be seen in FIG. 5B by comparing the position of the dotted substrate carrier and the position of the substrate carrier drawn with solid lines.

It is to be understood that the substrate carrier controller 530 may be configured for controlling the active magnetic elements 523′ for translationally aligning the substrate carrier 120 in a vertical direction, e.g. with a mask carrier as described herein. Further, by controlling the active magnetic elements, the substrate carrier 120 may be positioned into a target vertical position. The substrate carrier 120 may be maintained in the target vertical position under the control of the substrate carrier controller 530. Further, the substrate carrier controller 530 can be configured for controlling the active magnetic elements 523′ for angularly aligning the substrate carrier 120 with respect to a first rotation axis, e.g. a rotational axis perpendicular to the substrate surface, e.g. a rotational axis extending in a z-direction as exemplarily indicated in FIG. 5B.

According to some embodiments, which can be combined with other embodiments described herein, the apparatus can be configured for providing an alignment, particularly a contactless alignment, of the substrate carrier 120 with respect to the mask carrier 140, e.g. in a vertical direction, with an alignment range from 0.1 mm to 3 mm. Further, an alignment precision, particularly a contactless alignment precision, in the vertical direction can be 50 μm or below, for example 1 μm to 10 μm, such as 5 μm. Further, a rotational alignment precision, particularly a contactless rotational alignment precision, of the positioning arrangement can be 3° or below.

As described above, the one or more further active magnetic elements 513′ of the first drive sub-structure 510 can be configured for providing a driving force along the extension of the first track 112, e.g. the x-direction. It is to be understood that the substrate carrier controller 530 can be configured to control the one or more further active magnetic elements 513′ to provide for an alignment in a transport direction, for example the x-direction in FIGS. 5A and 5B. An alignment of the substrate carrier 120 in a transport direction (e.g. x-direction) can be provided with an alignment range extending along the length of the first track 112. In particular, an alignment precision, particularly a contactless alignment precision, in the transport direction can be 50 μm or below, for example 5 μm or μm.

Embodiments of the apparatus as described herein provide for a levitated substrate carrier movement which allows for a high precision in substrate positioning in a transport direction and/or a vertical direction. Further, embodiments of the apparatus as described herein provide for an improved alignment of a substrate carrier relative to a mask carrier, e.g. by horizontal and/or vertical and/or rotational alignment.

Turning now to FIG. 6, a schematic side view of the apparatus having the first guiding sub-structure 520 being a first magnetic guiding sub-structure and the first drive sub-structure 510 being a first magnetic drive sub-structure is illustrated. Further, FIG. 6 shows that the apparatus may have a second guiding sub-structure 522, such as a second magnetic guiding sub-structure, as well as a second drive sub-structure 512, such as a second magnetic drive sub-structure. With exemplary reference to FIG. 6, it is to be understood that the optional features of the first track arrangement as described with reference to FIGS. 5A and 5B, mutatis mutandis, may also be applied to the second track arrangement. In particular, the mask carrier 140 may include a first passive magnetic element 142 and a second passive magnetic element 144 as described with reference to FIGS. 5A and 5B. Further, the second guiding sub-structure 522 may include a plurality of active magnetic elements 523 and the second drive sub-structure 512 may include a plurality of further active magnetic elements 513, as described with reference to FIGS. 5A and 5B. Similarly to the substrate carrier controller 530 for controlling levitation and transportation of the substrate carrier 120, a mask carrier controller can be provided for controlling levitation and transportation of the mask carrier 140. In particular, the principle of controlling levitation and transportation of the mask carrier 140, mutatis mutandis, corresponds to the principle of controlling levitation and transportation of the substrate carrier 120 as described with reference to FIGS. 5A and 5B.

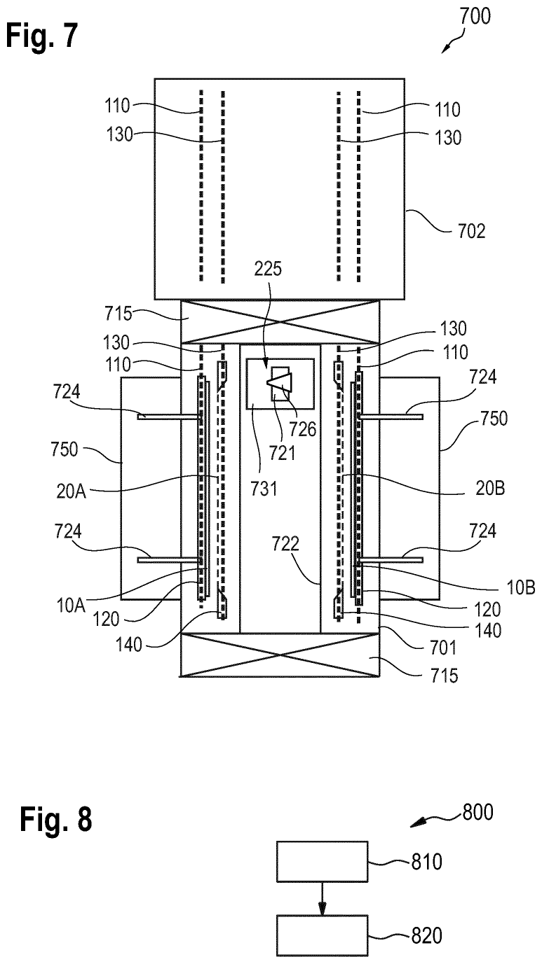

FIG. 7 shows a schematic view of a system 700 for vacuum processing of a substrate according to embodiments described herein.

The system 700 includes the apparatus for vacuum processing of a substrate according to the embodiments described herein, the substrate carrier 120 and the mask carrier 140. In some implementations, the first track arrangement 110 is configured for transportation of the substrate carrier 120 and the mask carrier 140, and/or the second track arrangement 130 is configured for transportation of the substrate carrier 120 and the mask carrier 140.

According to some embodiments, which can be combined with any other embodiments described herein, the system 700 includes the vacuum chamber (e.g. a vacuum processing chamber 701) having an apparatus according to any embodiments described herein. Further, the system 700 includes at least one further chamber 702 having a transport arrangement. The at least one further chamber 702 can be a rotation module, a transit module, or a combination thereof. In the rotation module, the track arrangement and the carrier(s) arranged thereon can be rotated around a rotational axis, such as a vertical rotation axis. As an example, the carrier(s) can be transferred from the left side of the system 700 to the right side of the system 700, or vice versa. The transit module can include crossing tracks such that carrier(s) can be transferred through the transit module in different directions, e.g., directions perpendicular to each other. The vacuum processing chamber 701 can be configured for depositing organic materials. A deposition source 225, particularly an evaporation source, can be provided in the vacuum processing chamber 701. The deposition source 225 can be provided on a track or linear guide 722, as exemplarily shown in FIG. 7. The linear guide 722 may be configured for the translational movement of the deposition source 225. Further, a drive for providing a translational movement of deposition source 225 can be provided. In particular, a transportation apparatus for contactless transportation of the deposition source 225 may be provided.

A source support 731 configured for the translational movement of the deposition source 225 along the linear guide 722 may be provided. The source support 731 can support an evaporation crucible 721 and a distribution assembly 726 provided over the evaporation crucible 721. Accordingly, the vapor generated in the evaporation crucible 721 can move upwardly and out of the one or more outlets of the distribution assembly. Accordingly, the distribution assembly 726 is configured for providing evaporated organic material, particularly a plume of evaporated source material, from the distribution assembly to the substrate.

As exemplarily shown in FIG. 7, the vacuum processing chamber 701 may have gate valves 715 via which the vacuum process chamber 701 can be connected to an adjacent further chamber 702, e.g. a routing module or an adjacent service module. In particular, the gate valves 715 allow for a vacuum seal to the adjacent further chamber and can be opened and closed for moving a substrate and/or a mask into or out of the vacuum processing chamber 701.

In the present disclosure, a “vacuum processing chamber” is to be understood as a vacuum chamber or a vacuum deposition chamber. The term “vacuum”, as used herein, can be understood in the sense of a technical vacuum having a vacuum pressure of less than, for example, 10 mbar. The pressure in a vacuum chamber as described herein may be between 10⁻⁵ mbar and about 10⁻⁸ mbar, specifically between 10⁻⁵ mbar and 10⁻⁷ mbar, and more specifically between about 10⁻⁶ mbar and about 10⁻⁷ mbar. According to some embodiments, the pressure in the vacuum chamber may be considered to be either the partial pressure of the evaporated material within the vacuum chamber or the total pressure (which may approximately be the same when only the evaporated material is present as a component to be deposited in the vacuum chamber). In some embodiments, the total pressure in the vacuum chamber may range from about 10⁻⁴ mbar to about 10⁻⁷ mbar, especially in the case that a second component besides the evaporated material is present in the vacuum chamber (such as a gas or the like).

With exemplary reference to FIG. 7, according to embodiments which can be combined with any other embodiment described herein, two substrates, e.g. a first substrate 10A and a second substrate 10B, can be supported on respective transportation tracks, such as respective first track arrangements 110 as described herein. Further, two tracks, e.g. two second track arrangements 120 as described herein, for providing mask carriers 140 thereon can be provided. In particular, the tracks for transportation of a substrate carrier 120 and/or a mask carrier 140 may be configured as described with reference to FIGS. 1 to 6.

In some embodiments, coating of the substrates may include masking the substrates by respective masks, e.g. by an edge exclusion mask or by a shadow mask. According to some embodiments, the masks, e.g. a first mask 20A corresponding to the first substrate 10A and a second mask 20B corresponding to the second substrate 10B, are provided in a mask carrier 140 to hold the mask in a predetermined position, as exemplarily shown in FIG. 7.

According to some embodiments, which can be combined with other embodiments described herein, the substrate is supported by the substrate carrier 120, which can be connected to an alignment system 750, e.g. by connecting elements 724. The alignment system 750 can be configured for adjusting the position of the substrate with respect to the mask. In particular, the alignment system 750 can be configured as described with respect to FIGS. 3, 4A and 4B. It is to be understood that the substrate can be moved relative to the mask in order to provide for a proper alignment between the substrate and the mask during deposition of the organic material. According to a further embodiment, which can be combined with other embodiments described herein, alternatively or additionally the mask carrier 140 holding the mask can be connected to the alignment system 750. Accordingly, either the mask can be positioned relative to the substrate or the mask and the substrate can both be positioned relative to each other. An alignment system as described herein may allow for a proper alignment of the masking during the deposition process, which is beneficial for high quality or OLED display manufacturing.

Examples of an alignment of a mask and a substrate relative to each other include alignment units, such as the alignment devices described with respect to FIGS. 3, 4A, 4B and 5, which can allow for a relative alignment in at least two directions defining a plane, which is essentially parallel to the plane of the substrate and the plane of the mask. For example, an alignment can at least be conducted in an x-direction and a y-direction, i.e. two Cartesian directions defining the above-described parallel plane. Typically, the mask and the substrate can be essentially parallel to each other. Specifically, the alignment can further be conducted in a direction essentially perpendicular to the plane of the substrate and the plane of the mask. Thus, an alignment unit is configured at least for an X-Y-alignment, and specifically for an X-Y-Z-alignment of the mask and the substrate relative to each other. One specific example, which can be combined with other embodiments described herein, is to align the substrate in x-direction, y-direction and z-direction to a mask, which can be held stationary in the vacuum processing chamber.

FIG. 8 shows a flow chart of a method 800 for transportation of a substrate carrier and a mask carrier in a vacuum chamber according to embodiments described herein. The method 800 can utilize the apparatuses and systems according to the present disclosure.

The method 800 includes, in block 810, contactlessly transporting the substrate carrier on a first track arrangement and the mask carrier on a second track arrangement, and, in block 820, contactlessly transporting the substrate carrier on the second track arrangement and the mask carrier on the first track arrangement.

According to embodiments described herein, the method for transportation of a substrate carrier and a mask carrier in a vacuum chamber can be conducted using computer programs, software, computer software products and the interrelated controllers, which can have a CPU, a memory, a user interface, and input and output devices being in communication with the corresponding components of the apparatus.

The present disclosure provides a first track arrangement for a substrate carrier and a second track arrangement for a mask carrier that are equally sized in at least one dimension. In other words, the mask carrier fits into the first track arrangement and the substrate carrier fits into the second track arrangement. The first track arrangement and the second track arrangement can be flexibly used while providing an accurate and smooth transportation of the carriers through the vacuum system. The holding arrangement allows for a precise alignment of the substrate with respect to the mask, or vice versa. A high quality processing results, e.g. for production of high resolution OLED devices, can be achieved.

While the foregoing is directed to embodiments of the disclosure, other and further embodiments of the disclosure may be devised without departing from the basic scope thereof, and the scope thereof is determined by the claims that follow.

1. An apparatus for vacuum processing of a substrate, comprising:
a vacuum chamber;
a first track arrangement configured for transportation of a substrate carrier and including a first portion configured to support the substrate carrier at a first end of the substrate and a second portion configured to support the substrate carrier at a second end of the substrate opposite the first end of the substrate;
a second track arrangement configured for transportation of a mask carrier and including a further first portion configured to support the mask carrier at a first end of a mask and a further second portion configured to support the mask carrier at a second end of the mask opposite the first end of the mask, wherein a first distance between the first portion and the second portion of the first track arrangement and a second distance between the further first portion and the further second portion of the second track arrangement are essentially the same; and
a holding arrangement configured for positioning the substrate carrier and the mask carrier with respect to each other.

2. The apparatus of claim 1, wherein the first track arrangement and the second track arrangement extend in a first direction, wherein the first track arrangement is configured for transportation of the substrate carrier at least in the first direction, and wherein the second track arrangement is configured for transportation of the mask carrier at least in the first direction.

3. The apparatus of claim 2, wherein the first portion and the further first portion are arranged in a first plane defined by the first direction and another direction perpendicular to the first direction, and wherein the second portion and the further second portion are arranged in a second plane defined by the first direction and the other direction.

4. The apparatus of claim 3, wherein the first direction is a horizontal direction and the other direction is another horizontal direction or a vertical direction.

5. The apparatus of claim 4, wherein the first distance and the second distance are defined in a direction perpendicular to the first direction and the other direction.

6. The apparatus of claim 2, further including a drive structure configured for contactlessly moving the substrate carrier and the mask carrier in the first direction, wherein the drive structure includes the first portion and the further first portion.

7. The apparatus of claim 2, further including a guiding structure configured for contactlessly levitating the substrate carrier and the mask carrier in the vacuum chamber, wherein the guiding structure includes the second portion and the further second portion.

8. The apparatus of claim 2, wherein the holding arrangement is configured to position the substrate carrier and the mask carrier with respect to each other in a direction different from the first direction.

9. The apparatus of claim 1, wherein the holding arrangement is arranged at at least one of a top wall and a bottom wall of the vacuum chamber.

10. The apparatus of claim 1, wherein the holding arrangement is arranged at a side wall of the vacuum chamber adjacent to the first track arrangement or the second track arrangement.

11. The apparatus of claim 1, wherein the holding arrangement is at least partially arranged between the first track arrangement and the second track arrangement.

12. The apparatus of claim 1, wherein the holding arrangement includes one or more piezoelectric actuators for positioning the substrate carrier and the mask carrier with respect to each other.

13. A system for vacuum processing of a substrate, comprising:
an apparatus for vacuum processing of a substrate comprising:
a vacuum chamber;
a first track arrangement configured for transportation of a substrate carrier and including a first portion configured to support the substrate carrier at a first end of the substrate and a second portion configured to support the substrate carrier at a second end of the substrate opposite the first end of the substrate;
a second track arrangement configured for transportation of a mask carrier and including a further first portion configured to support the mask carrier at a first end of a mask and a further second portion configured to support the mask carrier at a second end of the mask opposite the first end of the mask, wherein a first distance between the first portion and the second portion of the first track arrangement and a second distance between the further first portion and the further second portion of the second track arrangement are essentially the same; and
a holding arrangement configured for positioning the substrate carrier and the mask carrier with respect to each other;
the substrate carrier; and
the mask carrier.

14. The system of claim 13, wherein the first track arrangement is configured for transportation of the substrate carrier and the mask carrier, and wherein the second track arrangement is configured for transportation of the substrate carrier and the mask carrier.

15. A method for transportation of a substrate carrier and a mask carrier in a vacuum chamber, comprising:
contactlessly transporting the substrate carrier on a first track arrangement and the mask carrier on a second track arrangement; and
contactlessly transporting the substrate carrier on the second track arrangement and the mask carrier on the first track arrangement.

16. The apparatus of claim 1, wherein the holding arrangement is at least partially arranged between the first track arrangement and the second track arrangement.

17. The apparatus of claim 6, wherein the holding arrangement is at least partially arranged between the first track arrangement and the second track arrangement.

18. The apparatus of claim 7, wherein the holding arrangement is at least partially arranged between the first track arrangement and the second track arrangement.

19. The apparatus of claim 8, wherein the holding arrangement is at least partially arranged between the first track arrangement and the second track arrangement.

20. The system of claim 13, wherein the holding arrangement is at least partially arranged between the first track arrangement and the second track arrangement.
